(19) United States
(12) Patent Application Publication
(10) Pub. No.: US 2009/0211903 A1
(43) Pub. Date: Aug. 27, 2009

(54) INDIUM ZINC OXIDE BASED SPUTTERING TARGET, METHOD OF MANUFACTURING THE SAME, AND INDIUM ZINC OXIDE BASED THIN FILM

(75) Inventors: Yoon-Gyu LEE, Suwon-si (KR); Jin-Ho LEE, Suwon-si (KR); Yil-Hwan YOU, Suwon-si (KR); Ju-Ok PARK, Suwon-si (KR)

Correspondence Address: MCDERMOTT WILL & EMERY LLP, 600 13TH STREET, N.W., WASHINGTON, DC, 20005-3096, US

(73) Assignee: SAMSUNG CORNING PRECISION GLASS CO.,LTD.

(21) Appl. No.: 12/392,457

(22) Filed: Feb. 25, 2009

(30) Foreign Application Priority Data
Feb. 26, 2008 (KR) 10-2008-0017513

(51) Int. Cl. C23C 14/00; B29C 43/02

(52) U.S. Cl. 204/298.13; 264/681; 264/674

(57) ABSTRACT

Disclosed are an indium (In) zinc (Zn) oxide based sputtering target, a method of manufacturing the same, and an In Zn oxide based thin film deposited using the In Zn oxide based sputtering target. The In Zn oxide based sputtering target has a composition of (MO₂)ₓ(In₂O₃)_{y}(ZnO)_{z}, in which x:y is about 1:0.01 to 1:1, y:z is about 1:0.1 to 1:10, and M is at least one metal selected from a group consisting of hafnium (Hf), zirconium (Zr), and titanium (Ti).

### CROSS-REFERENCE TO RELATED APPLICATION

This application claims the benefit of Korean Patent Application No. 10-2008-0017513, filed on Feb. 26, 2008 in the Korean Intellectual Property Office, the disclosure of which is incorporated herein by reference.

### BACKGROUND

1. Field of the Invention

The present invention relates to manufacturing of a sputtering target and manufacturing of a thin film using the sputtering target, and more particularly, to an indium (In) zinc (Zn) oxide based sputtering target, a method of manufacturing the same, and an In Zn oxide based thin film deposited using the In Zn oxide based sputtering target.

2. Description of the Related Art

A thin film transistor (TFT) may be a small-sized multiplier tube shaped into a fine and thin film, and may be a three-terminal device including a gate, a source, and a drain. In a conventional art, a polycrystalline silicon film or an amorphous silicon film may be generally used as a channel layer of the TFT. However, in a case of the polycrystalline silicon film, electron mobility may be limited due to dispersion of electrons occurring in a polycrystalline particle interface. Conversely, in a case of the amorphous silicon film, the electron mobility may be significantly low, and a reliability of an element may be significantly reduced due to deterioration of the element occurring over time. In order to overcome these problems, there have been recently studies for forming the TFT channel layer using an oxide thin film, for example, a zinc (Zn) oxide based thin film instead of using the polycrystalline silicon film and the amorphous silicon film.

As examples of a method of forming the oxide thin film, a sputtering method using a polycrystalline sintered body as a target, a Pulse Laser Deposition (PLD) method, an electron beam deposition method, and the like may be given. Because the sputtering method may facilitate mass production, studies for manufacturing a target capable of depositing a thin film using the sputtering method are actively made.

The sputtering method may include a radio frequency (RF) sputtering method using a RF plasma and a direct current (DC) sputtering method using a DC plasma, according to a generation method of an argon plasma. The DC sputtering method may be generally utilized for industrial use due to its rapid deposition rate and simple operation and maintenance. However, in a case of a Zn oxide based sputtering target used for depositing the Zn oxide based thin film, a resistivity of the Zn oxide based sputtering target may be significantly high depending on a type and amount of a material to be doped, whereby it is impossible for the Zn oxide based sputtering target to be used in the DC sputtering.

### SUMMARY

An aspect of the present invention provides an indium (In) zinc (Zn) oxide based sputtering target having a low resistance.

An aspect of the present invention also provides an In Zn oxide based sputtering target capable of depositing an amorphous or nano-crystalline thin film at a low temperature.

An aspect of the present invention further provides an In Zn oxide based thin film having an excellent electron mobility and flatness.

An aspect of the present invention still further provides a method of manufacturing an In Zn oxide based sputtering target having a low resistivity and a high sintering density.

According to an aspect of the present invention, there is provided an In Zn oxide based sputtering target having a composition of (MO₂)ₓ(In₂O₃)_{y}(ZnO)_{z}, wherein x:y is about 1:0.01 to 1:1, y:z is about 1:0.1 to 1:10, and M is at least one metal selected from a group consisting of hafnium (Hf), zirconium (Zr), and titanium (Ti).

According to another aspect of the present invention, there is provided an In Zn oxide based thin film which is deposited using the above sputtering target in a DC sputtering, wherein an electron mobility may be about 1 cm²/V·s to 100 cm²/V·s.

According to further aspect of the present invention, there is provided a method of manufacturing an In Zn oxide based sputtering target, the method including: adding, in a slurry in which an indium oxide powder and a zinc oxide powder are added, at least one oxide powder selected from a group consisting of a hafnium oxide, a zirconium oxide, and a titanium oxide to thereby prepare a slurry mixture; adding a dispersant in the slurry mixture and wet-milling the slurry mixture; drying the slurry mixture to form a granular powder; pressing the granular powder to obtain a pressed body; and sintering the pressed body.

Additional aspects, features, and/or advantages of the invention will be set forth in part in the description which follows and, in part, will be apparent from the description, or may be learned by practice of the invention.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIG. 1 is a light transmittance graph in a visible ray region of an indium (In) zinc (Zn) oxide based thin film of Example 2; and

FIG. 2 is a photograph in which a surface roughness of an In Zn based thin film of Example 2 is measured using an Atomic Force Microscope (AFM).

### DETAILED DESCRIPTION

An indium (In) zinc (Zn) oxide based sputtering target, a method of manufacturing the same, and an In Zn oxide based thin film deposited using the In Zn oxide based sputtering target will be described hereinafter in detail.

The In Zn oxide based sputtering target according to an example embodiment basically includes an In oxide and a Zn oxide, and additionally includes at least one oxide selected from a hafnium (Hf) oxide, a zirconium (Zr) oxide, and a titanium (Ti) oxide. Specifically, the In Zn oxide based sputtering target has a composition of (MO₂)ₓ(In₂O₃)_{y}(ZnO)_{z}, and M is at least one metal selected from a group consisting of Hf, Zr, and Ti. Specifically, the In Zn oxide based sputtering target may have any composition of (HfO₂)ₓ(In₂O₃)_{y}(ZnO)_{z}, (ZrO₂)ₓ(In₂O₃)_{y}(ZnO)_{z}, and (TiO₂)ₓ(In₂O₃)_{y}(ZnO)_{z}.

Here, x:y may be about 1:0.01 to 1:1, and y:z may be about 1:0.1 to 1:10, and more preferably, x:y may be about 1:0.01 to 1:0.5, and y:z may be about 1:0.2 to 1:5. A ratio of x:y may exhibit an optimum electron mobility of the In Zn oxide based thin film, and may be determined according to a condition having semiconductor characteristics and a condition where a direct current (DC) sputtering is allowed to be performed. When x:y is outside a range of about 1:0.01 to 1:1, the DC sputtering may be difficult to be applicable due to non-conductive characteristics of the thin film and a high target resistivity. A ratio of y:z may be determined according to a condition capable of obtaining a thin film that exhibits amorphous or nano-crystalline characteristics. When y:z is outside a range of about 1:0.1 to 1:10, crystalline characteristics of the thin film may become stronger, causing the same problems as those in a polycrystalline silicon as a result. A ratio of z may preferably increase in terms of costs of raw materials. However, when the ratio of z is more than a certain value, the thin film may be poly-crystallized due to an increase in a Zn oxide property within the target, whereby an amorphous thin film may be difficult to be formed. As a result, the thin film may exhibit properties close to a transparent electrode rather than semiconductor characteristics. Thus, according to an example embodiment, a ratio of Hf:In:Zn, Zr:In:Zn, and Ti:In:Zn may be adjusted to manufacture the In Zn based sputtering target in which the DC sputtering is applicable, and an electrical resistivity is about 100 mΩ or less.

When an amount of M is overly added while being outside a composition ratio range according to the present example embodiment, M may remain as an impurity agglomerate while not being solution-dissolved in the In Zn oxide, thereby causing a local resistance of the target. Thus, the In Zn oxide based thin film characteristics may be deteriorated, and the thin film may be changed into a nonconductor. In addition, the DC sputtering may be difficult to be applicable, an abnormal discharge (arching) may occur at the time of sputtering, and the thin film may not function as an oxide semiconductor. Conversely, when the amount of M is insufficiently added while being outside the composition ratio range, the amorphous or nano-crystalline characteristics may not be exhibited.

When manufacturing the In Zn oxide based sputtering target, the In oxide may be added in the Zn oxide, and at least one oxide selected from a group consisting of the Hf oxide, the Zr oxide, and the Ti oxide may be additionally added in the target. Accordingly, an oxygen vacancy or an electric charge carrier such as an electron, etc., may be generated within a Zn oxide lattice, whereby electricity may flow in the target.

Because the Zn oxide is a material exhibiting non-conductivity as a material with a wide band gap, the above-mentioned oxides may be added in the Zn oxide as doping elements, whereby electricity may flow in the Zn oxide. In this instance, the doping elements may become impurity agglomerates depending on a type and amount of the doping element, causing problems as a result. However, in the In Zn oxide based sputtering target having the composition according to the present example, a substitution and solid-solution of each of the doping materials is excellently performed on the Zn oxide, a size of an In 2-phase of In, a 2-phase of Hf, and a 2-phase of Zr, that is, impurity agglomerates in which the solid-solution is not partially performed, is small. As a result, the abnormal discharge (arching) and nodule may be prevented from occurring due to the impurity agglomerates whose electrical resistivity is high at the time of sputtering.

To enable the DC sputtering to be applicable, a bulk resistance of the target is required to be several tens of ohms or less. When the electricity does not flow in the target at the time of sputtering, the RF sputtering is needed to be performed for thin film deposition, however, the RF sputtering may need a high processing cost, and may have lower efficiency as compared with the DC sputtering. However, according to an example embodiment, i) the In oxide and ii) at least one oxide selected from a group consisting of the Hf oxide, the Zr oxide, and the Ti oxide are added in the Zn oxide with a predetermined composition ratio, thereby reducing the resistivity of the In Zn oxide based sputtering target. Also, a size of the 2-phase of the added oxides becomes smaller such as about 1 μm or less to prevent occurrence of arching and nodule at the time of sputtering and to reduce the resistivity of the target, thereby increasing a processing efficiency of the target manufacturing. In this instance, when the In Zn oxide based sputtering target satisfies the composition of the present example embodiment, an amorphous transparent semiconductor thin film being excellent in the electron mobility may be formed using the DC sputtering.

Hereinafter, the method of manufacturing the In Zn oxide based sputtering target will be described in detail.

First, at least one oxide powder selected from a group consisting of the Hf oxide, the Zr oxide, and the Ti oxide is added in a slurry, in which an indium oxide powder and a zinc oxide powder are added, to thereby prepare a slurry mixture. Next, a dispersant is added in the slurry mixture, and the slurry mixture is wet-milled. Next, the slurry mixture is dried to form a granular powder, and the granular powder is pressed to obtain a pressed body Next, the pressed body is sintered.

When preparing the slurry mixture, at least one oxide powder of the Hf oxide, the Zr oxide, and the Ti oxide, a first dispersant, and water are mixed and wet-milled, the In oxide power, a second dispersant, and water are mixed and wet-milled, and the Zn oxide power, a third dispersant, and water are mixed and wet-milled, respectively. Next, the wet-milled powders are mixed. Here, the wet-milling may function to mill each of component particles, and to uniformly disperse the milled component particles. The dispersant may be used for the dispersing. As the dispersant, polycarbonic acids may be generally used, and more specifically, a polycarbonic acid-ammonium salt or a polyacrylic acid-ammonium salt may be used. The dispersant may be used alone or in any combination of two or more.

According to the present example, when preparing the slurry mixture, the preparation of the slurry mixture may not be limited to the above-mentioned example. As an example, the oxide powders such as the In oxide, the Zn oxide, and the Hf oxide are mixed in the slurry and milled, however, each of the oxide powders is preferably milled to adjust an average diameter of each of the oxide powders.

As described above, when individually adjusting a diameter of each of raw materials and mixing all together, a type and amount of the dispersant may be optimized according to surface characteristics of each of component particles, and then used. For example, when dispersing the Hf oxide, the Zr oxide, and the Ti oxide, about 0.8 wt % to 2.0 wt % of the polyacrylic acid-ammonium salt (having a molecular weight of about 2,000) may be used with respect to the oxide powder. Also, when dispersing the In oxide, about 0.5 wt % to 1.5 wt % of the polyacrylic acid-ammonium salt (having a molecular weight of about 5,000) may be used with respect to the In oxide powder, and when dispersing the Zn oxide, about 0.1 wt % to 0.5 wt % of the polyacrylic acid-ammonium salt (having a molecular weight of about 3,000) may be used with respect to the Zn oxide powder.

In this manner, the type, the molecular weight, and the amount of the added dispersant may vary depending on a type of the oxide powder to adjust a diameter of the powder. However, when the Hf oxide powder, the Zr oxide power, or the Ti oxide powder is mixed in the In oxide powder and Zn oxide powder to prepare the slurry mixture before performing the dispersing, about 0.5 wt % of the polyacrylic acid-ammonium salt (having a molecular weight of about 3,000 to 20,000) may be added in water with respect to the entire oxide powder.

The oxide powders acting as a dopant such as the Zn oxide powder and the In oxide powder are respectively milled before adding the oxide powders as the slurry mixture, whereby the oxide powders having a small average diameter may be mixed with each other in a powder state. As a result, a solid-solution effect in which component elements added in an interstitial site or substitutional site within a Zn oxide lattice are doped may increase. Also, a size of an impurity (or dopant) agglomerate in which each of the In powder, the Hf powder, the Zr powder, and the Ti powder is locally agglomerated within the target may become small, and thereby a ratio of the 2-phase having about 1 μm or more may be about 5% or less.

In addition, the oxide powders may be required to be significantly and uniformly mixed in a granular powder state after an average diameter of the In oxide, the Zn oxide, the Hf oxide, the Zr oxide, and the Ti oxide used as a raw material is adjusted. In this case, the average diameter of each of the oxide powders is desirably less than about 1 μm. Otherwise, an additional processing cost may be needed to obtain a uniform mixture of the raw materials, and a specific component element within the sputtering target may be locally concentrated, whereby it is difficult to obtain composition uniformity after performing film depositing. Accordingly, physical properties of the thin film and reliability may be reduced.

Therefore, the dispersing in which the slurry mixture is uniformly dispersed using wet-milling may be performed. In this instance, the wet-milling may function to mill each of the component particles, and to uniformly disperse at least three oxide particles in a state of being milled. Thus, the above described dispersant may be added. When performing the dispersing, a viscosity of a slurry obtained through the wet-milling may be preferably about 100 cps or less. When the viscosity thereof is more than about 100 cps, a size of the particle within the slurry is relatively large, thereby reducing a dispersing property and a density of a sintered body obtained after performing sintering.

When the mixed slurry is completed after performing the dispersing, a bonding agent such as polyvinyl alcohol (PVA), polyethylene glycol (PEG), and the like may be added in the slurry. The bonding agent may improve a degree of strength and sintering density of a pressed body when manufacturing the pressed body in obtaining the sputtering target. The bonding agent may be used alone or in any combination of two or more. A type and added amount of the bonding agent according to the present example embodiment may be not particularly limited. Specifically, the bonding agent may be applicable as long as the strength of the pressed body is maintained. The added amount of the bonding agent may be about 0.01 wt % to 5 wt % within the slurry, and preferably, about 0.5 wt % to 3 wt %.

The dispersant and the bonding agent may be preferably used within the above-described amount, since a density of a sintered body manufactured afterwards is reduced when an organic solvent such as the dispersant, the bonding agent, and the like is overly used.

Next, the slurry mixture with the bonding agent added therein may be manufactured to be a granular powder through spray-drying. A technique of the spray-drying is well-known in the art, and thus may not be particularly limited. However, the granular powder may exhibit an apparent density of about 1.3 or more according to the American Society for Testing and Materials (ASTM) of an international standards organization. When the apparent density of the granular powder is less than about 1.3, the sintering density of the sintered body may be reduced, causing abnormal discharge in sputtering the target as a result.

Next, the spray-dried granular powder may be first-pressed in a general cold press method, and second-pressed in a cold isostatic press method. In this instance, a pressing pressure of the cold press method may be preferably about 300 kg/cm² to 700 kg/cm². When the pressing pressure is less than about 300 kg/cm² or more than about 700 kg/cm², a great difference in a lengthwise and breadthwise shrinking degree may be shown while being subjected to the cold isostatic pressing and sintering, and thereby the pressed body or the sintered body may be bent.

Next, when the pressing is completed, the pressed body may be sintered to obtain a sputtering target. Component elements constituting the target obtained through the sintering may be uniformly presented, and a bulk resistance of the sintered body may be maintained to be less than about 100 mΩ, so that the DC sputtering may be applicable.

An electrical resistivity of the In Zn oxide based sputtering target may increase as an amount of Hf and Zr increases in a mixture of In, Zn, and Hf, or a mixture of In, Zn, and Zr, and thereby a sintering condition when performing the sintering may be adjusted. For example, in order to reduce electrical resistivity characteristics of the target to enable the DC sputtering to be applicable, the sintering may be performed at a temperature of about 1,300° C. to 1,500° C. and under an oxygen atmosphere or an air atmosphere.

Hereinafter, the In Zn oxide based thin film manufactured using the In Zn oxide based sputtering target according to an example embodiment will be described in detail.

The composition of the sputtering target and a composition of the thin film may be different from each other in a multi-element base being different from a single element. For example, a thin film exhibiting semiconductor characteristics may not be obtained from the sputtering target with the same composition as that of the thin film. This is because characteristics of the deposited thin film may vary according to a type of a power, a gas atmosphere, and the like when performing the sputtering.

Also, the In Zn oxide based thin film may be formed into an amorphous thin film or a crystalline thin film by adjusting the composition of the target and a sputtering condition. Similarly, the In Zn oxide based thin film may be formed into a semiconductor thin film or a conductive thin film according to the composition of the target and the condition of the sputtering. As an example, in order to manufacture a transparent semiconductor thin film using the In Zn oxide based sputtering target, a volume of an oxygen gas may be about 0% to 30% in a mixed gas atmosphere of an argon gas and the oxygen gas when performing the sputtering. In the above-described sputtering condition, the In Zn oxide based thin film deposited using the DC sputtering may be an amorphous thin film. Also, by adjusting the composition of the target and sputtering condition, a deposition speed of the thin film may increase.

The In Zn oxide based thin film according to an example embodiment may exhibit a high transmittance, for example, a visible ray transmittance of about 90% or more at about 550 μm. Also, a surface Root Mean Square (RMS) roughness of the thin film may be about 100 Å or less, which is excellent in a surface flatness of the thin film. As a result, a thickness of a gate insulating layer may be reduced when manufacturing a thin film transistor device. Also, an electron mobility of the In Zn oxide based thin film may be about 1 cm²/V·s to 100 cm²/V·s.

Hereinafter, the present invention will be described in detail by examples. It is to be understood, however, that these examples are for illustrative purpose only, and are not construed to limit the scope of the present invention.

### Example 1

### HIZO (Hafnium Indium Zinc Oxide) Sputtering Target Manufacturing

A Hf oxide power, an In oxide power, and a Zn oxide power each having an average diameter of about 1 μm or less were prepared so that a ratio of Hf:In:Zn was about 1:0.4:0.4. Next, the prepared oxide powders were respectively mixed in a mixture in which water and a polycarbonic acid-ammonium salt are mixed, and each of the mixtures was wet-milled for about one hour using a hard zirconia-ball mill. Next, the wet-milled mixtures were mixed to prepare a slurry mixture. Next, the polycarbonic acid-ammonium salt was added in the slurry mixture, wet-milled for about one hour using the hard zirconia-ball mill, and then polyvinyl alcohol (PVA) was added. Next, the slurry mixture with the PVA added therein was formed into a dried granular powder using a spray dryer. Next, the granular powder was first-pressed with a pressure of about 500 kg/cm² using a cold press method, and the first-pressed granular powder was second-pressed with a pressure of about 600 kg/cm² using a cold isostatic press method. Next, the pressed body was sintered for about one hour at a high temperature of about 1,400° C. under an oxygen atmosphere to thereby manufacture a HIZO sintered body. Next, a sputtering surface of the sintered body was grinded using a grinder to obtain a diameter of about 3 inch and a thickness of about 5 mm, and was jointed with a backing plate using an In based alloy to thereby manufacture a HIZO sputtering target. An electrical resistivity of the HIZO sputtering target was about 75 mΩ.

### Example 2

### HIZO Thin Film Manufacturing

The HIZO sputtering target manufactured through Example 1 was mounted on a magnetron sputtering device, and an oxygen and argon gas were injected at room temperature to deposit a transparent HIZO thin film having a thickness of about 150 nm on a glass substrate. In this instance, the HIZO thin film was deposited under a mixed gas atmosphere of the argon gas and the oxygen gas in which a volume of the oxygen gas was about 15%. In addition, a DC power was about 100 W In this instance, in the DC power of about 100 W, the HIZO thin film was deposited at a deposition speed (11 Å/sec) faster than a deposition speed (9 Å/sec) of a conventional Gallium Indium Zinc Oxide (GIZO).

The HIZO thin film manufactured through Example 2 was analyzed using X-ray diffraction (XRD), and as a result, the HIZO thin film exhibited amorphous characteristics. An electrical conductivity of the HIZO thin film was measured, and as a result, a range value of 1 E⁻⁴ to 3 E⁻³ (ohm·cm)⁻¹ being suitable for a thin film transistor (TFT) device was shown. Also, an electron mobility of the HIZO thin film was excellent.

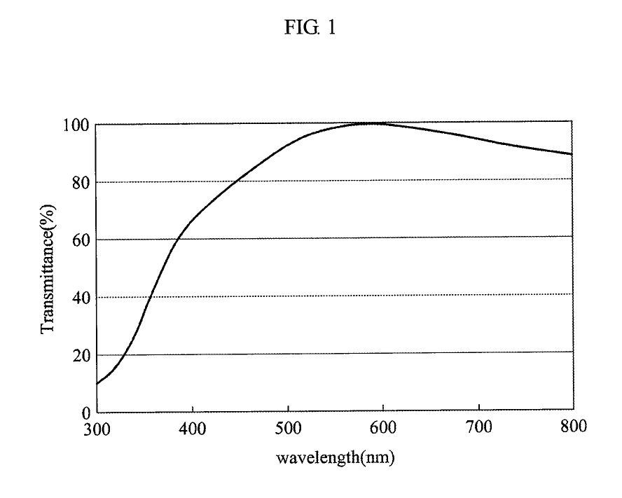

A light transmittance in a visible ray range with respect to the glass substrate on which the HIZO thin film is deposited was measured, and a result is shown in FIG. 1. Referring to FIG. 1, the HIZO thin film exhibited a high light transmittance of about 98% at about 550 nm. Thus, the HIZO thin film may be applicable in the TFT device.

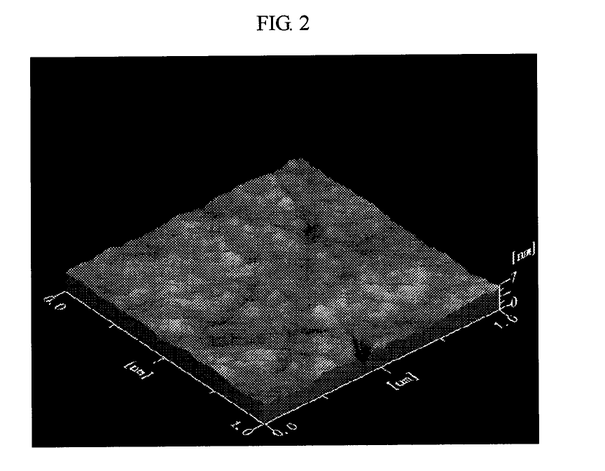

A surface roughness of the HIZO thin film was measured using an Atomic Force Microscope (AFM), and a result is shown in FIG. 2. Referring to FIG. 2, a surface Root Mean Square (RMS) roughness of the HIZO thin film was about 3 Å. In general, a surface flatness of the HIZO thin film was significantly excellent as compared with a surface RMS roughness of several hundred Å of a polycrystalline silicon thin film, which is crystallized using a conventional excimer laser.

As described above, according to the present invention, the In Zn oxide based sputtering target may be used in the DC sputtering method due to its low electrical resistivity, and prevent a plasma abnormal discharge from occurring by means of micro pores existing inside a sintered body due to its high sintering density. Also, because a size of a 2-phase agglomerate existing inside the In Zn oxide based target is relatively small, the In Zn oxide based thin film with a uniform composition distribution may be deposited, and abnormal discharge and nodule may be prevented from occurring. Also, the In Zn oxide based thin film according to example embodiments may exhibit excellent electron mobility and flatness, thereby increasing element reliability. In the method of manufacturing the In Zn oxide based sputtering target according to example embodiments, uniform composition distribution of component elements contained within the target may be obtained.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. An indium zinc oxide based sputtering target having a composition of (MO₂)ₓ(In₂O₃)_{y}(ZnO)_{z}, wherein x:y is about 1:0.01 to 1:1, y:z is about 1:0.1 to 1:10, and M is at least one metal selected from a group consisting of hafnium (Hf), zirconium (Zr), and titanium (Ti).

2. The indium zinc oxide based sputtering target of claim 1, wherein the sputtering target is used in a direct current (DC) sputtering.

3. The indium zinc oxide based sputtering target of claim 1, wherein the sputtering target has an electrical resistivity of about 100 mΩ or less.

4. An indium zinc oxide based thin film which is deposited using the sputtering target of claim 1 in a DC sputtering, wherein an electron mobility is about 1 cm²/V·s to 100 cm²/V·s.

5. The indium zinc oxide based thin film of claim 4, wherein the thin film is deposited under a mixed gas atmosphere of an argon gas and an oxygen gas in which a volume of the oxygen gas is about 0% to 30%.

6. The indium zinc oxide based thin film of claim 4, wherein the thin film is amorphous.

7. The indium zinc oxide based thin film of claim 4, wherein a surface Root Mean Square (RMS) roughness of the thin film is about 100 Å or less.

8. A method of manufacturing an indium zinc oxide based sputtering target, the method comprising:
adding, in a slurry in which an indium oxide powder and a zinc oxide powder are added, at least one oxide powder selected from a group consisting of a hafnium oxide, a zirconium oxide, and a titanium oxide to thereby prepare a slurry mixture;
adding a dispersant in the slurry mixture and wet-milling the slurry mixture;
drying the slurry mixture to form a granular powder;
pressing the granular powder to obtain a pressed body; and
sintering the pressed body.

9. The method of claim 8, wherein the adding of the at least one oxide powder includes:
mixing and wet-milling a first oxide powder, a first dispersant, and water to prepare a first oxide slurry;
mixing and wet-milling the indium oxide powder, a second dispersant, and water to prepare an indium oxide slurry;
mixing and wet-milling the zinc oxide powder, a third dispersant, and water to prepare a zinc oxide slurry; and
mixing the first oxide slurry, the indium oxide slurry, and the zinc oxide slurry.

10. The method of claim 9, wherein at least one of the first dispersant, the second dispersant, and the third dispersant is a polycarbonic acid-ammonium salt or a polyacrylic acid-ammonium salt.

11. The method of claim 9, wherein about 0.8 to 2.0 wt % of the first dispersant is contained in the first oxide slurry, about 0.5 to 1.5 wt % of the second dispersant is contained in the indium oxide slurry, and about 0.1 to 0.5 wt % of the third dispersant is contained in the zinc oxide slurry.

12. The method of claim 8, wherein the granular powder exhibits an apparent density of about 1.3 or more by American Society for Testing and Materials (ASTM) of an international standards organization.

13. The method of claim 8, wherein the sintering is performed at a temperature of about 1,300° C. to 1,500° C. and under an oxygen atmosphere or an air atmosphere.
